(19) United States
(12) Patent Application Publication
(10) Pub. No.: US 2024/0051500 A1
(43) Pub. Date: Feb. 15, 2024

(54) METHOD AND DEVICE FOR CONTROLLING KEY

(71) Applicant: Tuneit Inc., Seongnam-si (KR)

(72) Inventors: Chung Young OH, Seongnam-si (KR); Bongyong SONG, Suwon-si (KR); Kichang YI, Suwon-si (KR)

(21) Appl. No.: 18/268,659

(22) PCT Filed: Jan. 11, 2021
(86) PCT No.: PCT/KR2021/000296

§ 371 Date: Jun. 21, 2023

(30) Foreign Application Priority Data
Dec. 22, 2020 (KR) 10-2020-0181095

(51) Int. Cl. B60R 25/40; B60R 25/24; H03K 17/56

(52) U.S. Cl. CPC B60R 25/403; B60R 25/24; H03K 17/56

(57) ABSTRACT

A method and device for controlling a key are provided. The method for controlling a key may include a step of performing authentication with a remote controller control device configured to apply a driving signal to a remote controller circuit, when the remote controller control device receives a vehicle control request from a user device, a step of receiving a power application signal and an enable signal from the remote controller control device, and a step of applying power to the remote controller circuit.

### TECHNICAL FIELD

The present invention relates to a method and device for controlling a key.

### BACKGROUND ART

With the widespread use of mobile devices such as smart phones or wearable devices such as smart watches, technologies for controlling vehicles or electronic devices from such mobile devices or wearable devices have been gaining traction, and such technologies have made it possible for users to control their vehicles or electronic devices even if they do not always carry their physical keys. For example, in the case of a vehicle, a physical remote controller key may be mounted in the vehicle, and control on the vehicle or an electronic device from a mobile device or a wearable device (hereinafter, referred to as a ‘user device’) may be implemented in such a manner that when the corresponding control request is received, the request is transmitted to the physical remote controller key. To this end, an intermediate device may be installed inside or outside the vehicle and be implemented so as to transmit control requests between the user device and the physical remote controller key.

In the key control scheme which is implemented in that manner, the intermediate device may receive a control request from the user device and directly control the physical remote controller key according to the control request. For example, when receiving a control request for starting the vehicle from the user device, the intermediate device may output a driving signal for driving a start key or button on the physical remote controller. Accordingly, when receiving the corresponding driving signal, the physical remote controller key can actually start the vehicle.

By the way, if it becomes possible for people with malicious intent to operate the physical remote controller key in other ways, not by a signal output from the intermediate device, the vehicle may be stolen. For this reason, measures are required to prevent the physical remote controller key from being operated in an unallowed manner in the key control scheme implemented in the above-mentioned way to steal the vehicle.

### DISCLOSURE

### Technical Problem

The present invention attempts to provide a method and device for controlling a key, capable of preventing a physical remote controller key from being operated in an unallowed manner in a key control scheme using an intermediate device for transmitting control requests between a user device and a physical remote controller key to steal the vehicle.

### Technical Solution

An exemplary embodiment of the present invention provides a method for controlling a key, which may include a step of performing authentication with a remote controller control device configured to apply a driving signal to a remote controller circuit, when the remote controller control device receives a vehicle control request from a user device, a step of receiving a power application signal and an enable signal from the remote controller control device, and a step of applying power to the remote controller circuit.

The step of applying power may include a step of applying a normal voltage to the remote controller circuit when the power application signal is received in the case where the authentication succeeds and the enable signal is in a first state.

The step of applying power may include a step of not applying any voltage to the remote controller circuit unless the power application signal is received in the case where the authentication succeeds and the enable signal is in a first state.

The step of applying power may include a step of not applying any voltage to the remote controller circuit in the case where the authentication succeeds and the enable signal is in a second state.

The step of applying power may include a step of applying a break voltage to the remote controller circuit when the power application signal is received in the case where the authentication has failed.

The step of applying the break voltage may include a step of raising the power application signal to a predetermined voltage capable of breaking the remote controller circuit by a step-up circuit, and a step of applying the raised voltage as the break voltage to the remote controller circuit.

The case where the authentication has failed may include the case where there has been no attempt to perform authentication with the remote controller control device, or the case where there has been an attempt to perform authentication with the remote controller control device but the authentication has failed.

The step of applying the break voltage may include a step of attempting secondary authentication with the remote controller control device before applying the break voltage to the remote controller circuit, and a step of applying the break voltage to the remote controller circuit in the case where the secondary authentication has failed.

The step of applying the break voltage may further include a step of applying a normal voltage to the remote controller circuit in the case where the secondary authentication succeeds and the enable signal is in a first state.

The step of applying the break voltage may further include a step of not applying any voltage to the remote controller circuit in the case where the secondary authentication succeeds and the enable signal is in a second state.

Another exemplary embodiment of the present invention provides a device for controlling a key, which may include a first transistor that is turned on so as to output a voltage raised by a step-up circuit, a second transistor that is turned on so as to output a power application signal received from a remote controller control device, and a processor, and the processor may perform authentication with the remote controller control device when the remote controller control device receives a vehicle control request from a user device, and receive a power application signal and an enable signal from the remote controller control device, and control the first transistor and the second transistor such that power is applied to a remote controller circuit.

In the case where the authentication succeeds and the enable signal is in a first state, when receiving the power application signal, the processor may turn on the second transistor, thereby applying a normal voltage to the remote controller circuit.

In the case where the authentication succeeds and the enable signal is in a first state, the processor may not apply any voltage to the remote controller circuit unless the power application signal is received.

In the case where the authentication succeeds and the enable signal is in a second state, the processor may not apply any voltage to the remote controller circuit.

In the case where the authentication has failed, when the power application signal is received, the processor may turn on the first transistor, thereby applying a break voltage to the remote controller circuit.

The break voltage may be a predetermined voltage to which the power application signal is raised by the step-up circuit and which can break the remote controller circuit.

The case where the authentication has failed may include the case where there has been no attempt to perform authentication with the remote controller control device, or the case where there has been an attempt to perform authentication with the remote controller control device but the authentication has failed.

The processor may attempt secondary authentication with the remote controller control device before applying the break voltage to the remote controller circuit, and turn on the first transistor, thereby applying the break voltage to the remote controller circuit, in the case where the secondary authentication has failed.

In the case where the secondary authentication succeeds and the enable signal is in a first state, the processor may turn on the second transistor, thereby applying a normal voltage to the remote controller circuit.

In the case where the secondary authentication succeeds and the enable signal is in a second state, the processor may not apply any voltage to the remote controller circuit.

### Advantageous Effects

According to the exemplary embodiments of the present invention, it is possible to detect an attempt to operate a physical remote controller key in an unallowed manner in a key control scheme using an intermediate device for transmitting control requests between a user device and a physical remote controller key in order to steal a vehicle, and break the remote controller key when the detected attempt is determined as being a carjacking attempt, thereby being capable of preventing vehicle theft.

### DESCRIPTION OF THE DRAWINGS

FIG. 1 is a conceptual view for explaining a key control system according to an exemplary embodiment of the present invention.

FIG. 2 and FIG. 3 are block diagrams for explaining a key control device according to an exemplary embodiment of the present invention.

FIG. 4 is a circuit diagram for explaining a power control unit according to the exemplary embodiment of the present invention.

FIG. 5 is a view for explaining a key control method according to an exemplary embodiment of the present invention.

FIG. 6 is a view for explaining a key control method according to an exemplary embodiment of the present invention.

FIG. 7 is a view for explaining a key control method according to an exemplary embodiment of the present invention.

FIG. 8 is a view for explaining a key control method according to an exemplary embodiment of the present invention.

FIG. 9 is a view for explaining a key control method according to an exemplary embodiment of the present invention.

FIG. 10 is a block diagram for explaining a computing device for implementing a key control method, a key control device, and a user device according to an exemplary embodiment of the present invention.

### MODE FOR INVENTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Throughout this specification and the claims, unless explicitly described to the contrary, the word “comprise”, and variations such as “comprises” or “comprising”, will be understood to imply the inclusion of stated elements but not the exclusion of any other elements. In addition, terms such as “-er”, “-or”, and “module” described in the specification mean units for processing at least one function or operation, and can be implemented by hardware or software, or by combinations of hardware and software. Further, at least some parts of a key control method, a key control device, and a user device according to exemplary embodiments to be described below may be configured as programs or software, and the programs or the software may be stored in computer-readable media.

Throughout this specification, the term “key” may refer to an automotive remote controller, but is also used to include all of other remote controllers capable of remotely controlling various electronic devices. Sometimes, the term “key” may be used interchangeably with the term “remote controller”.

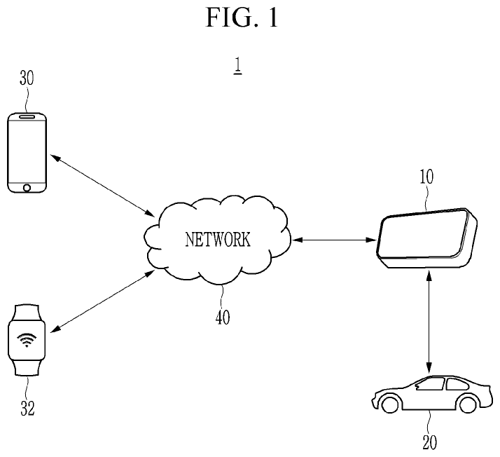

FIG. 1 is a view for explaining a key control system according to an exemplary embodiment of the present invention.

Referring to FIG. 1, a key control system 1 according to an exemplary embodiment of the present invention may include a key control device 10, another device 20 which is controlled by the key control device 10, and user devices 30 and 32 capable of controlling the key control device 10.

First, in the present exemplary embodiment, for ease of explanation, the case where another device 20 is a vehicle will be mainly described. In other words, in the present exemplary embodiment, the case where a user controls another device 20, i.e., a vehicle, using the key control device 10 will be described. However, the scope of the present invention is not limited thereto, and various components and features of the present invention to be described below may also be applied to any electronic devices which can be operated by manipulating remote controllers. As will be described below, the key control device 10 controls another device 20, using a remote controller circuit 14 corresponding to a physical remote controller. In this case, the remote controller circuit 14 may be a remote controller circuit for a vehicle, but may also be a remote controller circuit for any electronic device. Examples of such an electronic device may include various household appliances that can be controlled by remote controllers, such as air conditioners, fans, vacuum cleaners, refrigerators, and the like, but the scope of the present invention is not limited thereto.

The user devices 30 and 32 may run an application to make it possible for the user to operate another device 20 using the key control device 10. The user devices 30 and 32 may be implemented as mobile devices or wearable devices having user input interfaces and processors, and the application may be executed on the processors. However, the scope of the present invention is not limited thereto, and the user devices 30 and 32 may be implemented as arbitrary computing devices.

The user devices 30 and 32 may receive user inputs from the user through the user input interfaces. For example, the user devices 30 and 32 may receive touch inputs or gesture inputs which the user inputs on a touch panel, using a user input interface.

The user devices 30 and 32 may transmit control requests to the key control device 10 through a network 40. In the present exemplary embodiment, the network 40 may include a Wi-Fi network, a mobile communication network such as a 3G, 4G, or 5G network, a wireless network including a Bluetooth network and the like, a wireless network including a local area network (LAN), or a combination of wireless networks and wired networks. However, the scope of the present invention is not limited thereto, and the network 40 may include any form of network over which the key control device 10 and the user devices 30 and 32 can exchange data.

The key control device 10 may control another device 20 in response to control requests which are received from the user devices 30 and 32. To this end, the key control device 10 may include a remote controller control device 12, the remote controller circuit 14, and a power control unit 16.

The remote controller control device 12 may control the remote controller circuit 14 in response to control requests which are received from the user devices 30 and 32, and the power control unit 16 may apply power for operating the remote controller circuit 14, to the remote controller circuit 14. The remote controller control device 12, the remote controller circuit 14, and the power control unit 16 may be packaged in one case, and be installed as the key control device inside or outside another device 20.

Particularly, the remote controller control device 12, the remote controller circuit 14, and the power control unit 16 may be implemented such that they are buried in a high-strength insulator when wiring finishes, thereby making it difficult for people with malicious intent to break them.

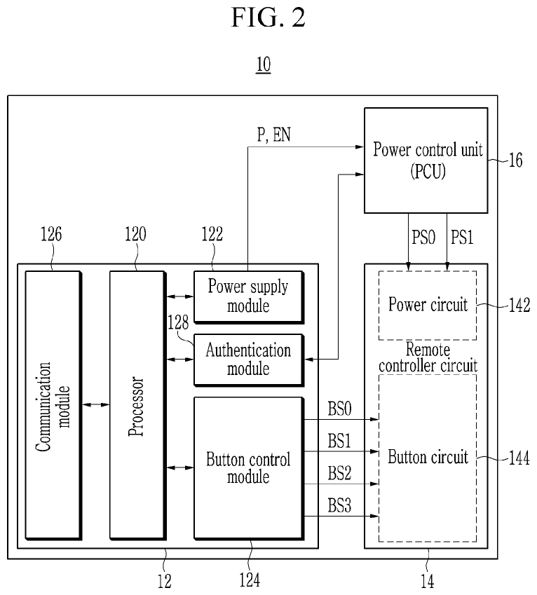

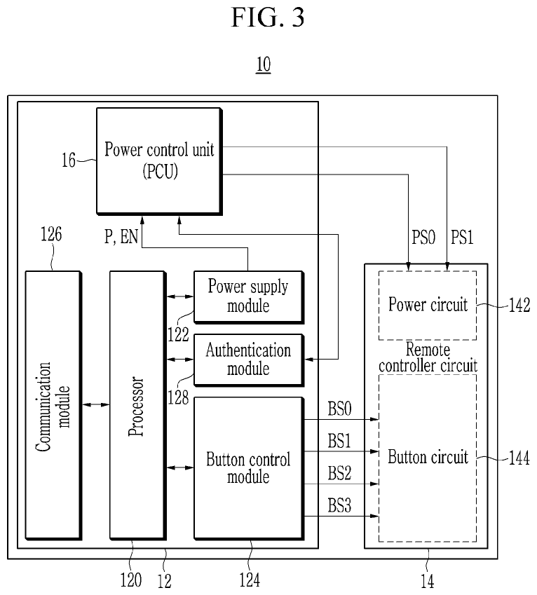

Hereinafter, the key control device 10 will be described in detail with reference to FIG. 2 and FIG. 3.

FIG. 2 and FIG. 3 are views for explaining a key control device according to an exemplary embodiment of the present invention.

Referring to FIG. 2, the key control device 10 may include the remote controller control device 12, the remote controller circuit 14, and the power control unit 16. Here, the power control unit 16 may also be referred to as the PCU (Power Control Unit).

First, the remote controller circuit 14 will be described. The remote controller circuit 14 may be a physical remote controller manufactured so as to correspond to a vehicle or an arbitrary electronic device. Specifically, the remote controller circuit 14 may include a printed circuit board (PCB) mounted in the physical remote controller. The PCB may include a power circuit 142, a button circuit 144, and other circuit elements. The power circuit 142 and the button circuit 144 are components which are generally included in the PCB regardless of the manufacturer of the vehicle or the electronic device; however, the specific control or operation manner of the remote controller circuit 14, or detailed specifications such as the number of buttons mounted on the remote controller circuit may differ depending on each vehicle or electronic device manufacturer.

The power circuit 142 is a circuit for supplying power to the remote controller circuit 14, and the power circuit 142 may receive power from the power control unit 16. To this end, the power circuit 142 may have a plurality of terminals including a plus terminal and a minus terminal.

The button circuit 144 may refer to a circuit having one or more buttons for operating the remote controller circuit 14. When the remote controller circuit 14 is used as it is, the user may directly push the buttons disposed on the button circuit 144 to control another device 20. Alternatively, the button circuit 144 may receive driving signals from the remote controller control device 12 as will be described below, whereby the same effect as that when one or more buttons have been pushed may occur. As a result, the button circuit can control another device 20. To this end, the button circuit 144 may have a plurality of terminals for receiving driving signals from the remote controller control device 12.

Also, the remote controller circuit 14 may include a communication module (not shown in the drawings) for performing communication with another device 20. For example, the remote controller circuit 14 may transmit a command to another device 20 through the communication module, using a radio frequency (RF) signal having a predetermined frequency or a frequency in a predetermined band. It goes without saying that the scope of the present invention is not limited thereto, and the remote controller circuit 14 may be implemented so as to control another device 20 using other kinds of signals. It has been described above with respect to FIG. 1 that the remote controller control device 12, the remote controller circuit 14, and the power control unit 16 may be packaged in one case and be installed as the key control device inside or outside another device 20; however, in this case, the key control device 10 may be installed inside or outside another device 20, for example, within a distance within which communication using RF signals is possible.

The remote controller control device 12 may output button driving signals BS0 to BS3 to the remote controller circuit 14, according to control requests which are received from the user devices 30 and 32. To this end, the remote controller control device 12 may include a processor 120, a power supply module 122, a button control module 124, a communication module 126, and an authentication module 128.

The processor 120 may generally control the remote controller control device 12, and perform a specific operation of outputting the button driving signals BS0 to BS3 to the remote controller circuit 14 according to control requests which are received from the user devices 30 and 32.

The power supply module 122 may transmit a power application signal P and an enable signal EN to the power control unit 16. Specifically, the power supply module 122 may provide the power application signal P and the enable signal EN to the power control unit 16 through terminals provided in the power control unit 16. The power control unit 16 may provide power supply voltages PS0 and PS1 to the remote controller circuit 14 according to operation modes to be described below.

The button control module 124 may provide the button driving signals BS0, BS1, BS2, and BS3 to the remote controller circuit 14. Here, the button driving signals BS0 to BS3 may refer to button on signals for switching one or more buttons of the remote controller circuit 14 to an ON state, and may also refer to button off signals for switching one or more buttons of the remote controller circuit 14 to an OFF state.

For example, the first button driving signal BS0 may refer to a first button on signal or a first button off signal for switching a first button implemented on the button circuit 144 to the ON state or the OFF state, and the second button driving signal BS1 may refer to a second button on signal or a second button off signal for switching a second button implemented on the button circuit 144 to the ON state or the OFF state. Further, the third button driving signal BS2 may refer to a third button on signal or a third button off signal for switching a third button implemented on the button circuit 144 to the ON state or the OFF state, and the fourth button driving signal BS3 may refer to a fourth button on signal or a fourth button off signal for switching a fourth button implemented on the button circuit 144 to the ON state or the OFF state.

In FIG. 2, only four button driving signals are shown taking the case where the remote controller control device 12 controls four buttons as an example; however, the scope of the present invention is not limited thereto.

The remote controller control device 12 may receive control requests from the user devices 30 and 32 through the communication module 126. In the present exemplary embodiment, the remote controller control device 12 may receive control requests from the user devices 30 and 32 through the communication module 126 implemented so as to access a Wi-Fi network, a mobile communication network such as a 3G, 4G, or 5G network, a wireless network including a Bluetooth network and the like, a wireless network including a LAN, or a combination of wireless networks and wired networks; however, the scope of the present invention is not limited thereto.

The authentication module 128 may perform authentication between the remote controller control device 12 and the power control unit 16. The power control unit 16 may provide the power supply voltages PS0 and PS1 to the remote controller circuit 14 when authentication between the remote controller control device 12 and the power control unit 16 succeeds, according to the operation modes to be described below.

Further, the remote controller control device 12 may be powered by a battery, or may be powered externally. In the latter case, for example, when the key control device 10 is installed inside a vehicle, the remote controller control device 12 may receive power from the vehicle, and when the key control device is installed outside an air conditioner, the remote controller control device 12 may receive power from the air conditioner or from a power source disposed near the air conditioner.

According to the content described with reference to FIG. 1 and FIG. 2, in one scenario, the application which is executed in the user devices 30 and 32 may display an image of a remote start button of the vehicle on the touch panels of the user devices 30 and 32. When the user clicks or touches the remote start button image, the application may detect whether a click event or a touch event has occurred.

When it is detected that a click event or a touch event has occurred, the application may transmit a control request for controlling the vehicle, to the key control device 10. Accordingly, the remote controller control device 12 may apply a driving signal to the remote controller circuit 14 in response to the corresponding control request, such that the remote controller circuit 14 performs remote start control on the vehicle.

Referring to FIG. 3, the power control unit 16 may be implemented so as to be mounted, particularly, inside the remote controller control device 12. For example, the power control unit 16 may be implemented on the same circuit board together with the remote controller control device 12, or may be implemented such that the circuit board of the power control unit 16 and the circuit board of the remote controller control device 12 are packaged as one module, or the power control unit 16 may be mounted inside the remote controller control device 12 in various inexplicit manners, or may even be implemented as one single circuit which performs all of the functions of the power control unit 16 and the remote controller control device 12.

In all descriptions of the present exemplary embodiment, the above description made with respect to FIG. 1 and FIG. 2 is applied as it is. Therefore, redundant descriptions will not be made herein.

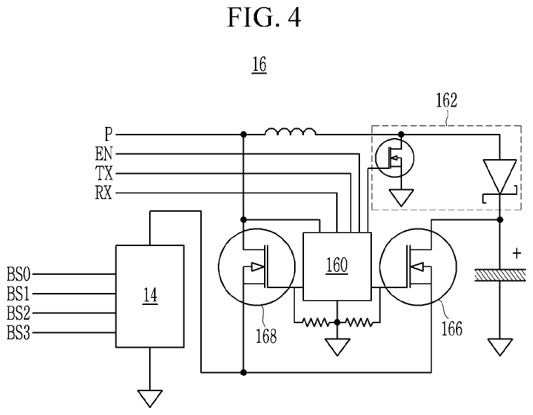

FIG. 4 is a circuit diagram for explaining the power control unit according to the exemplary embodiment of the present invention.

Referring to FIG. 4, the power control unit 16 according to the exemplary embodiment of the present invention may include a processor 160, a step-up circuit 162, a first transistor 166, and a second transistor 168.

The step-up circuit 162 may raise the power application signal P to a predetermined voltage. Here, the power application signal P may be a normal voltage capable of driving the remote controller circuit 14, for example, the voltage of 3.3 V, and the predetermined voltage may be a voltage capable of breaking the remote controller circuit 14, for example, the voltage of 24 V. It goes without saying that these specific voltage values may vary as much as necessary, depending on implementation purposes.

The first transistor 166 may be turned on under the control of the processor 160, so as to output the voltage raised by the step-up circuit 162 to the remote controller circuit 14.

The second transistor 168 may be turned on under the control of the processor 160 so as to output the power application signal P, i.e., the voltage received from the remote controller control device 12 to the remote controller circuit 14.

When the remote controller control device 12 receives a vehicle control request from the user device 30, the processor 160 may perform authentication with the remote controller control device 12 through terminals TX and RX, and receive the power application signal P and the enable signal EN from the remote controller control device 12, and control the first transistor 166 and the second transistor 168 such that power is applied to the remote controller circuit 14.

In an exemplary embodiment, in the case where the processor 160 has succeeded in authentication and the enable signal EN is in a first state, when the power application signal P is received, the processor may turn on the second transistor 168 such that the normal voltage is applied to the remote controller circuit 14. Here, the first state may refer to logical 1 or true. This case may correspond to the case where the key control device 10 operates normally, i.e., the case where the power control unit 16 receives the power application signal P from the remote controller control device 12 while the enable signal EN which is received from the remote controller control device 12 is in the ON state.

In another exemplary embodiment, in the case where the processor 160 has succeeded in authentication and the enable signal EN is in the first state, the processor may not apply any voltage to the remote controller circuit 14 unless the power application signal P is received. In this case, the enable signal EN which is received from the remote controller control device 12 is in the ON state, but the power control unit 16 does not receive the power application signal P from the remote controller control device 12. Therefore, the power control unit 16 cannot apply power to the remote controller circuit 14.

In yet another exemplary embodiment, in the case where the processor 160 has succeeded in authentication and the enable signal EN is in a second state, the processor may not apply any voltage to the remote controller circuit 14. Here, the second state may refer to logical 0 or false. This case corresponds to the case where the enable signal EN which is received from the remote controller control device 12 is in the OFF state. Therefore, regardless of whether the power application signal P has been received, the power control unit 16 cannot apply power to the remote controller circuit 14.

In still another exemplary embodiment, in the case where the processor 160 has failed in authentication, when the power application signal P is received, the processor may turn on the first transistor 166 such that a break voltage is applied to the remote controller circuit 14. Here, the break voltage may refer to a predetermined voltage to which the power application signal P is raised by the step-up circuit 162 and which can break the remote controller circuit 14.

Here, the case where authentication has failed may include the case where there has been no attempt to perform authentication with the remote controller control device 12, or the case where there has been an attempt to perform authentication with the remote controller control device 12 but the authentication has failed. Particularly, the case where the power application signal P has been received although there has been no attempt to perform authentication with the remote controller control device 12 may refer to a situation where a person with malicious intent has removed the wiring line between the remote controller control device 12 and the remote controller circuit 14 and has applied a predetermined signal to the remote controller circuit 14 in an unallowed manner to operate the physical remote controller key in order to carjack.

In this case, the processor 160 may attempt secondary authentication with the remote controller control device 12 before applying the break voltage to the remote controller circuit 14. When even the secondary authentication fails, the processor 160 may turn on the first transistor 166 such that the break voltage is applied to the remote controller circuit 14, thereby being capable of breaking the remote controller circuit 14. Accordingly, it is possible to prevent the physical remote controller key from being operated in an unallowed manner.

When the processor 160 attempts secondary authentication with the remote controller control device 12 before applying the break voltage to the remote controller circuit 14, and succeeds in the secondary authentication, if the enable signal EN is in the first state, the processor may turn on the second transistor 168 such that the normal voltage is applied to the remote controller circuit 14.

On the contrary, when the processor 160 attempts secondary authentication with the remote controller control device 12 before applying the break voltage to the remote controller circuit 14, and succeeds in the secondary authentication, if the enable signal EN is in the second state, the processor may not apply any voltage to the remote controller circuit 14.

In this way, it is possible to detect an attempt to operate a physical remote controller key in an unallowed manner in a key control scheme using an intermediate device for transmitting control requests between a user device and a physical remote controller key in order to steal a vehicle, and break the remote controller key when the detected attempt is determined as being a carjacking attempt, thereby being capable of preventing vehicle theft.

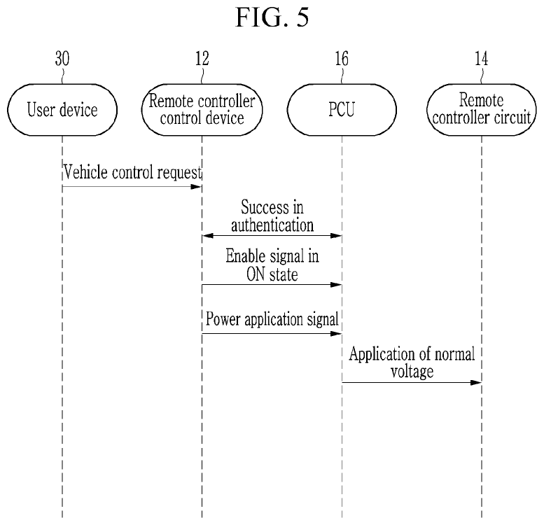

Hereinafter, key control methods according to exemplary embodiments of the present invention will be described in detail with reference to FIG. 5 to FIG. 9.

FIG. 5 is a view for explaining a key control method according to an exemplary embodiment of the present invention.

Referring to FIG. 5, the key control method according to the exemplary embodiment of the present invention may include a step in which the remote controller control device 12 for applying a driving signal to the remote controller circuit 14 receives a vehicle control request from the user device 30 (S401), a step in which the power control unit 16 performs authentication with the remote controller control device 12 (S403), a step in which the power control unit 16 receives the power application signal P and the enable signal EN from the remote controller control device 12 (S405), and a step in which the power control unit 16 applies power to the remote controller circuit 14 (S407).

The present exemplary embodiment corresponds to the case where the key control device 10 operates normally, i.e., the case where authentication succeeds in STEP S403, and in STEP S405, the enable signal EN which is received from the remote controller control device 12 is in the ON state and the power control unit 16 receives the power application signal P from the remote controller control device 12. Therefore, in STEP S407, the power control unit 16 can apply the normal voltage to the remote controller circuit 14.

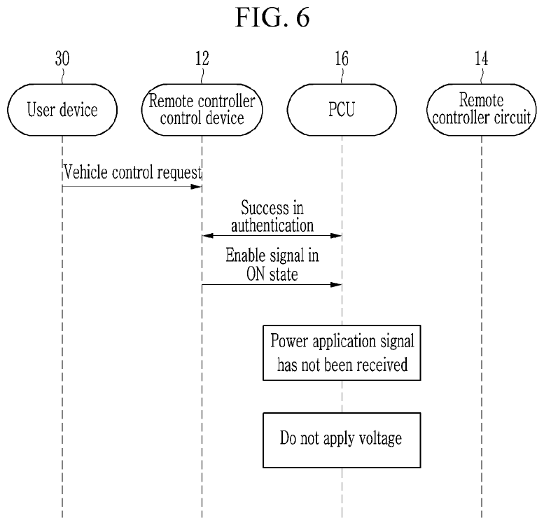

FIG. 6 is a view for explaining a key control method according to an exemplary embodiment of the present invention.

Referring to FIG. 6, the key control method according to the exemplary embodiment of the present invention may include a step in which the remote controller control device 12 for applying a driving signal to the remote controller circuit 14 receives a vehicle control request from the user device 30 (S501), a step in which the power control unit 16 performs authentication with the remote controller control device 12 and succeeds in the authentication (S503), and a step in which the power control unit 16 receives the enable signal EN which is in the ON state from the remote controller control device 12 (S505), and in the present exemplary embodiment, since the power control unit 16 has not received the power application signal P, the power control unit may not apply any voltage to the remote controller circuit 14.

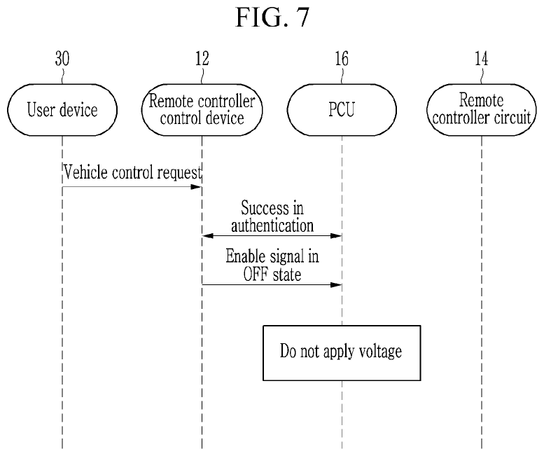

FIG. 7 is a view for explaining a key control method according to an exemplary embodiment of the present invention.

Referring to FIG. 7, the key control method according to the exemplary embodiment of the present invention may include a step in which the remote controller control device 12 for applying a driving signal to the remote controller circuit 14 receives a vehicle control request from the user device 30 (S601), a step in which the power control unit 16 performs authentication with the remote controller control device 12 and succeeds in the authentication (S603), and a step in which the power control unit 16 receives the enable signal EN which is in the OFF state from the remote controller control device 12 (S605), and in the present exemplary embodiment, since the power control unit 16 has not received the enable signal EN in the ON state, the power control unit may not apply any voltage to the remote controller circuit 14.

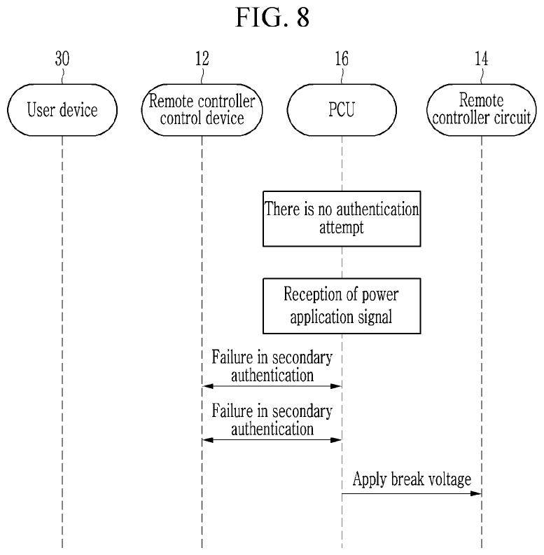

FIG. 8 is a view for explaining a key control method according to an exemplary embodiment of the present invention.

Referring to FIG. 8, when there has been no attempt to perform authentication between the power control unit 16 and the remote controller control device 12, and the power control unit 16 has received the power application signal, i.e., in a situation where a person with malicious intent has removed the wiring line between the remote controller control device 12 and the remote controller circuit 14 and has applied a predetermined signal to the remote controller circuit 14 in an unallowed manner to operate the physical remote controller key in order to steal the vehicle, the key control method according to the exemplary embodiment of the present invention may perform one or more times of secondary authentication between the power control unit 16 and the remote controller control device 12, and when even the secondary authentication fails, the power control unit 16 may apply the break voltage to the remote controller circuit 14, thereby breaking the remote controller circuit 14. Accordingly, it is possible to prevent the physical remote controller key from being operated in an unallowed manner.

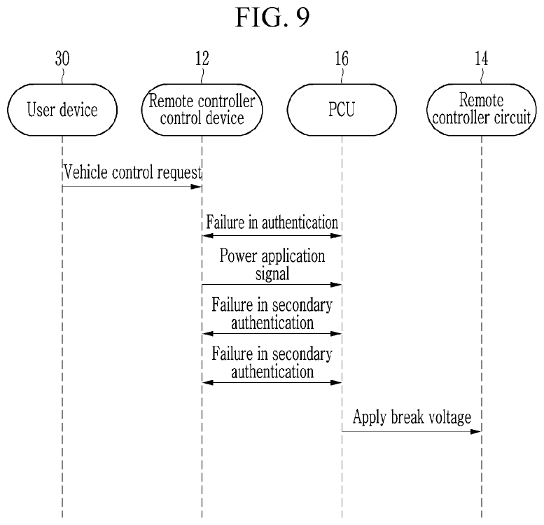

FIG. 9 is a view for explaining a key control method according to an exemplary embodiment of the present invention.

Referring to FIG. 9, the key control method according to the exemplary embodiment of the present invention may include a step in which the remote controller control device 12 for applying a driving signal to the remote controller circuit 14 receives a vehicle control request from the user device 30 (S801), a step in which the power control unit 16 performs authentication with the remote controller control device 12 and fails in the authentication (S803), and a step in which the power control unit 16 receives the power application signal P from the remote controller control device 12 (S805). This case may be determined as being an abnormal situation where there is a risk of carjacking, and one or more times of secondary authentication may be performed between the power control unit 16 and the remote controller control device 12, and when even the secondary authentication fails, the power control unit 16 may apply the break voltage to the remote controller circuit 14, thereby breaking the remote controller circuit 14. Accordingly, it is possible to prevent the physical remote controller key from being operated in an unallowed manner.

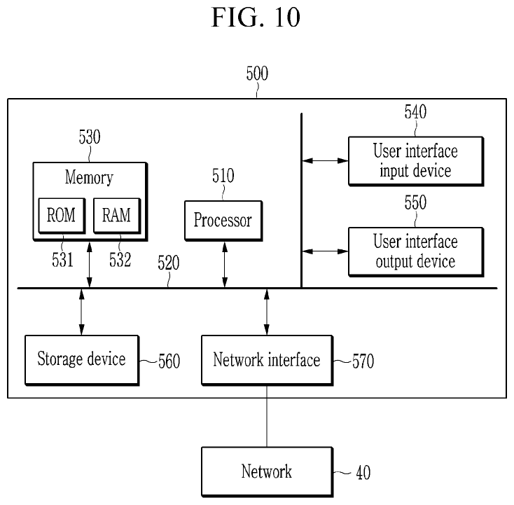

FIG. 10 is a block diagram for explaining a computing device for implementing a key control method, a key control device, and a user device according to an exemplary embodiment of the present invention.

Referring to FIG. 10, the key control method, the key control device, and the user device according to the exemplary embodiment of the present invention may be implemented using a computing device 500.

The computing device 500 may include at least one of a processor 510, a memory 530, a user interface input device 540, a user interface output device 550, and a storage device 560 which perform communication with one another via a bus 520. The computing device 500 may also include a network interface 570 which is electrically connected to a network 40, for example, a wireless network. The network interface 570 may transmit or receive signals to or from other entities via the network 40.

The processor 510 may be implemented with various types, such as a micro controller unit (MCU), an application processor (AP), a central processing unit (CPU), a graphic processing unit (GPU), and the like, and may be an arbitrary semiconductor device that executes instructions stored in the memory 530 or the storage device 560. The processor 510 may be configured to implement the functions and methods described with respect to FIG. 1 to FIG. 9.

The memory 530 and the storage device 560 may include various forms of volatile or non-volatile storage media. For example, the memory may include a read-only memory (ROM) 531 and a random access memory (RAM) 532. In the exemplary embodiment of the present invention, the memory 530 may be located inside or outside the processor 510, and the memory 530 may be coupled to the processor 510 through various known means.

Further, at least some of the key control methods, the key control device, and the user devices according to the exemplary embodiments of the present invention may be implemented as programs or software which is executed in the computing device 500, and the programs or software may be stored in computer-readable media.

Furthermore, at least some of the key control methods, the key control device, and the user devices according to the exemplary embodiments of the present invention may be implemented as hardware which can be electrically coupled to the computing device 500.

According to the exemplary embodiments of the present invention described above, it is possible to detect an attempt to operate a physical remote controller key in an unallowed manner in a key control scheme using an intermediate device for transmitting control requests between a user device and a physical remote controller key in order to steal a vehicle, and break the remote controller key when the detected attempt is determined as being a carjacking attempt, thereby being capable of preventing vehicle theft.

While this invention has been described in connection with what is presently considered to be practical exemplary embodiments, it is to be understood that the invention is not limited to the disclosed embodiments. On the contrary, it is intended to cover various modifications and equivalent arrangements made using the basic concept of this invention defined in the appended claims by those of ordinary skill in the art to which this invention pertain.

1. A method for controlling a key, comprising:
a step of performing authentication with a remote controller control device configured to apply a driving signal to a remote controller circuit, when the remote controller control device receives a vehicle control request from a user device;
a step of receiving a power application signal and an enable signal from the remote controller control device; and
a step of applying power to the remote controller circuit.

2. The method for controlling a key according to claim 1, wherein
the step of applying power includes a step of applying a normal voltage to the remote controller circuit when the power application signal is received in the case where the authentication succeeds and the enable signal is in a first state.

3. The method for controlling a key according to claim 1, wherein
the step of applying power includes a step of not applying any voltage to the remote controller circuit unless the power application signal is received in the case where the authentication succeeds and the enable signal is in a first state.

4. The method for controlling a key according to claim 1, wherein
the step of applying power includes a step of not applying any voltage to the remote controller circuit in the case where the authentication succeeds and the enable signal is in a second state.

5. The method for controlling a key according to claim 1, wherein
the step of applying power includes a step of applying a break voltage to the remote controller circuit when the power application signal is received in the case where the authentication has failed.

6. The method for controlling a key according to claim 5, wherein
the step of applying the break voltage includes the following:
a step of raising the power application signal to a predetermined voltage capable of breaking the remote controller circuit by a step-up circuit; and
a step of applying the raised voltage as the break voltage to the remote controller circuit.

7. The method for controlling a key according to claim 5, wherein
the case where the authentication has failed includes the case where there has been no attempt to perform authentication with the remote controller control device, or the case where there has been an attempt to perform authentication with the remote controller control device but the authentication has failed.

8. The method for controlling a key according to claim 5, wherein
the step of applying the break voltage includes the following:
a step of attempting secondary authentication with the remote controller control device before applying the break voltage to the remote controller circuit; and
a step of applying the break voltage to the remote controller circuit in the case where the secondary authentication has failed.

9. The method for controlling a key according to claim 8, wherein
the step of applying the break voltage further includes a step of applying a normal voltage to the remote controller circuit in the case where the secondary authentication succeeds and the enable signal is in a first state.

10. The method for controlling a key according to claim 8, wherein
the step of applying the break voltage further includes a step of not applying any voltage to the remote controller circuit in the case where the secondary authentication succeeds and the enable signal is in a second state.

11. A device for controlling a key, comprising:
a first transistor that is turned on so as to output a voltage raised by a step-up circuit;
a second transistor that is turned on so as to output a power application signal received from a remote controller control device; and
a processor, wherein
the processor performs the following:
performing authentication with the remote controller control device when the remote controller control device receives a vehicle control request from a user device;
receiving a power application signal and an enable signal from the remote controller control device; and
controlling the first transistor and the second transistor such that power is applied to a remote controller circuit.

12. The device for controlling a key according to claim 11, wherein
in the case where the authentication succeeds and the enable signal is in a first state, when receiving the power application signal, the processor turns on the second transistor, thereby applying a normal voltage to the remote controller circuit.

13. The device for controlling a key according to claim 11, wherein
in the case where the authentication succeeds and the enable signal is in a first state, the processor does not apply any voltage to the remote controller circuit unless the power application signal is received.

14. The device for controlling a key according to claim 11, wherein
in the case where the authentication succeeds and the enable signal is in a second state, the processor does not apply any voltage to the remote controller circuit.

15. The device for controlling a key according to claim 11, wherein
in the case where the authentication has failed, when the power application signal is received, the processor turns on the first transistor, thereby applying a break voltage to the remote controller circuit.

16. The device for controlling a key according to claim 15, wherein
the break voltage is a predetermined voltage to which the power application signal is raised by the step-up circuit and which can break the remote controller circuit.

17. The device for controlling a key according to claim 15, wherein
the case where the authentication has failed includes the case where there has been no attempt to perform authentication with the remote controller control device, or the case where there has been an attempt to perform authentication with the remote controller control device but the authentication has failed.

18. The device for controlling a key according to claim 15, wherein
the processor performs the following:
attempting secondary authentication with the remote controller control device before applying the break voltage to the remote controller circuit; and
turning on the first transistor, thereby applying the break voltage to the remote controller circuit, in the case where the secondary authentication has failed.

19. The device for controlling a key according to claim 18, wherein
in the case where the secondary authentication succeeds and the enable signal is in a first state, the processor turns on the second transistor, thereby applying a normal voltage to the remote controller circuit.

20. The device for controlling a key according to claim 18, wherein
in the case where the secondary authentication succeeds and the enable signal is in a second state, the processor does not apply any voltage to the remote controller circuit.
